(19) United States
(12) Patent Application Publication
(10) Pub. No.: US 2015/0056743 A1
(43) Pub. Date: Feb. 26, 2015

(54) MANUFACTURING METHOD OF SOLAR CELL

(71) Applicant: Shoichi Karakida, Tokyo (JP)

(72) Inventor: Shoichi Karakida, Tokyo (JP)

(73) Assignee: MITSUBISHI ELECTRIC CORPORATION, Tokyo (JP)

(21) Appl. No.: 14/379,851

(22) PCT Filed: Mar. 12, 2012
(86) PCT No.: PCT/JP2012/056330

§ 371 Date: Aug. 20, 2014

(51) Int. Cl. H01L 31/18; H01L 31/0236

(52) U.S. Cl. CPC H01L 31/18; H01L 31/02363
USPC 438/71

(57) ABSTRACT

A manufacturing method of a solar cell includes a protection-film forming step of forming a protection film on one surface side of a semiconductor substrate, a first processing step of forming a plurality of first openings having a shape close to a desired opening shape and a size smaller than a target opening size in the protection film by a method having relatively high processing efficiency, a second processing step of forming second openings in the protection film by expanding the first openings up to the target opening size by a method having relatively high processing accuracy, and an etching step of forming an asperity structure having the a concave portion in an inverted pyramid shape on the one surface side of the semiconductor substrate by performing anisotropic wet etching on the semiconductor substrate in a region under the second openings via the second openings.

### FIELD

The present invention relates to a manufacturing method of a solar cell.

### BACKGROUND

Conventionally, bulk type solar cells are typically manufactured by the following method. For example, a p-type silicon substrate is prepared first as a first conductivity type substrate, and a damaged layer on the silicon surface generated when being sliced from a cast ingot is removed by, for example, several wt % to 20 wt % caustic soda or carbonated caustic soda and in a thickness of 10 micrometers to 20 micrometers. Thereafter, anisotropic etching is performed with a solution in which IPA (isopropyl alcohol) is added to a similar low concentration alkaline solution, and a texture is formed so as to expose a silicon (111) surface.

Subsequently, the p-type silicon substrate is processed in a mixed gas atmosphere of, for example, phosphorous oxychloride (POCl₃), nitrogen, and oxygen for example at a temperature of 800° C. to 900° C. for several tens of minutes, thereby uniformly forming an n-type layer on the entire surface of the p-type silicon substrate as a second conductivity type impurity layer. By setting the sheet resistance of the n-type layer uniformly formed on the surface of the p-type silicon substrate to approximately 30 Ω/□ to 80 Ω/□, excellent electric property of a solar cell can be acquired. Because the n-type layer is uniformly formed on the surface of the p-type silicon substrate, the front surface and the back surface of the p-type silicon substrate are electrically connected. To interrupt the electrical connection, the facet region of the p-type silicon substrate is removed by dry etching to expose the p-type silicon. As another method to be performed to remove the influence of the n-type layer, there is a method of performing facet separation by a laser. Thereafter, the substrate is immersed in a hydrofluoric acid solution and a glassy (PSG: Phospho-Silicate Glass) layer deposited on the surface during a diffusion process is removed by etching.

Next, as an insulating film (an anti-reflective film) for preventing reflection, an insulating film such as a silicon dioxide film, a silicon nitride film, a titanium oxide film is formed on the surface of the n-type layer on the light-receiving surface side with a uniform thickness. When the silicon dioxide film is to be formed as the anti-reflective film, film formation is performed, for example, by a plasma CVD method, using SiH₄ gas and NH₃ gas as raw materials, at a temperature of 300° C. or higher under reduced pressure. The refraction index of the anti-reflective film is approximately 2.0 to 2.2, and the optimum film thickness is approximately 70 nanometers to 90 nanometers. It is to be noted that the anti-reflective film formed in this manner is an insulating body and the structure obtained by simply forming a light-receiving surface side electrode on the anti-reflective film does not function as a solar cell.

Subsequently, by using a mask for forming a grid electrode and for forming a bus electrode, silver paste to be the light-receiving surface side electrode is applied to the anti-reflective film in the shape of the grid electrode and the shape of the bus electrode by a screen printing method and is dried.

Back aluminum electrode paste to be a back aluminum electrode and back silver paste to be a back silver bus electrode are applied to the back surface of the substrate, respectively, in the shape of the back aluminum electrode and the shape of the back silver bus electrode by the screen printing method and dried.

The electrode paste applied to the front and back surfaces of the p-type silicon substrate is then baked simultaneously at a temperature of approximately 600° C. to 900° C. for several minutes. With this process, the grid electrode and the bus electrode are formed as the light-receiving surface side electrode on the anti-reflective film, and the back aluminum electrode and the back silver bus electrode are formed as the back surface-side electrode on the back surface of the p-type silicon substrate. On the front surface side of the p-type silicon substrate, the silver material comes in contact with silicon while the anti-reflective film is melting by the glass material contained in the silver paste, and is re-solidified. Accordingly, conduction between the light-receiving surface side electrode and the silicon substrate (the n-type layer) is ensured. This process is referred to as “fire-through method”. Furthermore, the back aluminum electrode paste reacts with the back surface of the silicon substrate, to form a p+ layer (BSF (Back Surface Field)) immediately below the back aluminum electrode.

### CITATION LIST

### Non Patent Literature

Non Patent Literature 1: Jianhua Zhao et. Al. “High efficiency PERT cells on n-type silicon substrates” Proceedings 29th IEEE Photovoltaic Specialists Conference pp 218-221 IEEE, Piscataway, USA 2002

### SUMMARY

### Technical Problem

To improve the photoelectric conversion efficiency in the solar cell manufactured in this manner, it is essential that the texture structure formed on the surface of the silicon substrate can capture sunlight to the silicon substrate efficiently. As the texture structure that can capture sunlight to the silicon substrate efficiently, for example, Non Patent Literature 1 discloses an “inverted” pyramid texture structure as one of the optimum structures. The inverted pyramid texture structure is a texture structure that includes microasperity (texture) in an inverted pyramid shape.

Such an inverted pyramid texture structure is manufactured in the following manner. First, an etching mask is formed on a silicon substrate. Specifically, a silicon nitride (SiN) film is formed by the plasma CVD method, or a silicon dioxide (SiO₂) film or the like is formed by thermal oxidation. Openings are then formed in the etching mask corresponding to the size of the microasperity in the inverted pyramid shape to be formed. The silicon substrate is then etched in an alkaline solution. With this process, etching of the surface of the silicon substrate proceeds via the openings, and a slow-reacting (111) surface is exposed, thereby forming the microasperity (texture) in the inverted pyramid shape on the surface of the silicon substrate. The inverted pyramid texture structure is acquired in this manner.

In the process of forming the inverted pyramid texture structure described above, the most complicated and time-consuming process is a process of forming the openings in the etching mask. When a photolithography technique, which is a general forming method of the openings in the etching mask, is used, many processes such as application of a photoresist to the etching mask, baking processing, exposure by using a photomask, development, baking, formation of the openings in the etching mask by etching, and removal of the resist need to be performed. Therefore, the method of using the photolithography technique has a problem in the productivity, because the process is complicated and the processing time becomes long.

Furthermore, in recent years, as another forming method of the openings in the etching mask, processing by using a laser has been studied. According to this method, by irradiating the etching mask with a laser beam, openings can be directly formed in the etching mask. However, in order to increase processing accuracy, the laser diameter of the laser beam needs to be narrowed and laser irradiation needs to be performed accurately several times. Therefore, processing by the laser requires a long processing time, thereby causing a problem in the productivity.

The present invention has been achieved to solve the above problems, and an object of the present invention is to provide a manufacturing method of a solar cell that can manufacture a solar cell having an inverted pyramid texture structure and excellent photoelectric conversion efficiency with good productivity.

### Solution to Problem

In order to solve the above problems and achieve the object, a manufacturing method of a solar cell according to the present invention is a manufacturing method of a solar cell including: a first step of forming an impurity diffusion layer by diffusing an impurity element having a second conductivity type on one surface side of a semiconductor substrate having a first conductivity type; a second step of forming, on the one surface side of the semiconductor substrate, a light-receiving surface side electrode that is electrically connected to the impurity diffusion layer; and a third step of forming a back surface-side electrode on another surface side of the semiconductor substrate, wherein the manufacturing method includes a fourth step of forming an asperity structure having a concave portion in an inverted pyramid shape on a surface of the one surface side of the semiconductor substrate at any point in time before the second step, and the fourth step includes a protection-film forming step of forming a protection film on the one surface side of the semiconductor substrate, a first processing step of forming a plurality of first openings having a shape close to a desired opening shape and a size smaller than a target opening size in the protection film by a method having relatively high processing efficiency, a second processing step of forming second openings in the protection film by expanding the first openings up to the target opening size by a method having relatively high processing accuracy, an etching step of forming the asperity structure having the concave portion in the inverted pyramid shape on the one surface side of the semiconductor substrate by performing anisotropic wet etching on the semiconductor substrate in a region under the second openings via the second openings, and a removing step of removing the protection film.

### Advantageous Effects of Invention

According to the present invention, an effect is obtained where an inverted pyramid texture structure can be formed with good productivity and highly accurately, and a solar cell having excellent photoelectric conversion efficiency can be manufactured with good productivity.

### BRIEF DESCRIPTION OF DRAWINGS

FIG. 1-1 is an explanatory diagram of the configuration of a solar cell according to embodiments of the present invention, and is a top view of the solar cell as viewed from a light receiving surface side.

FIG. 1-2 is an explanatory diagram of the configuration of the solar cell according to the embodiments of the present invention, and is a bottom view of the solar cell as viewed from the opposite side to the light receiving surface.

FIG. 1-3 is an explanatory diagram of the configuration of the solar cell according to the embodiments of the present invention, and is a sectional view of relevant parts of the solar cell along A-A direction in FIG. 1-1.

FIG. 2-1 is a sectional view of relevant parts for explaining an example of a manufacturing process of a solar cell according to a first embodiment of the present invention.

FIG. 2-2 is a sectional view of relevant parts for explaining an example of the manufacturing process of the solar cell according to the first embodiment of the present invention.

FIG. 2-3 is a sectional view of relevant parts for explaining an example of the manufacturing process of the solar cell according to the first embodiment of the present invention.

FIG. 2-4 is a sectional view of relevant parts for explaining an example of the manufacturing process of the solar cell according to the first embodiment of the present invention.

FIG. 2-5 is a sectional view of relevant parts for explaining an example of the manufacturing process of the solar cell according to the first embodiment of the present invention.

FIG. 2-6 is a sectional view of relevant parts for explaining an example of the manufacturing process of the solar cell according to the first embodiment of the present invention.

FIG. 2-7 is a sectional view of relevant parts for explaining an example of the manufacturing process of the solar cell according to the first embodiment of the present invention.

FIG. 3-1 is a top view of relevant parts for explaining a forming method of an inverted pyramid texture structure according to the first embodiment of the present invention.

FIG. 3-2 is a top view of relevant parts for explaining the forming method of the inverted pyramid texture structure according to the first embodiment of the present invention.

FIG. 3-3 is a top view of relevant parts for explaining the forming method of the inverted pyramid texture structure according to the first embodiment of the present invention.

FIG. 3-4 is a top view of relevant parts for explaining the forming method of the inverted pyramid texture structure according to the first embodiment of the present invention.

FIG. 4-1 is a sectional view of relevant parts for explaining the forming method of the inverted pyramid texture structure according to the first embodiment of the present invention.

FIG. 4-2 is a sectional view of relevant parts for explaining the forming method of the inverted pyramid texture structure according to the first embodiment of the present invention.

FIG. 4-3 is a sectional view of relevant parts for explaining the forming method of the inverted pyramid texture structure according to the first embodiment of the present invention.

FIG. 4-4 is a sectional view of relevant parts for explaining the forming method of the inverted pyramid texture structure according to the first embodiment of the present invention.

FIG. 5-1 is a top view of relevant parts for explaining a forming method of an inverted pyramid texture structure in a conventional manufacturing method of a solar cell.

FIG. 5-2 is a top view of relevant parts for explaining the forming method of the inverted pyramid texture structure in the conventional manufacturing method of a solar cell.

FIG. 5-3 is a top view of relevant parts for explaining the forming method of the inverted pyramid texture structure in the conventional manufacturing method of a solar cell.

FIG. 6-1 is a sectional view of relevant parts for explaining the forming method of the inverted pyramid texture structure in the conventional manufacturing method of a solar cell.

FIG. 6-2 is a sectional view of relevant parts for explaining the forming method of the inverted pyramid texture structure in the conventional manufacturing method of a solar cell.

FIG. 6-3 is a sectional view of relevant parts for explaining the forming method of the inverted pyramid texture structure in the conventional manufacturing method of a solar cell.

FIG. 7-1 is a top view of relevant parts for explaining a forming method of an inverted pyramid texture structure according to a second embodiment of the present invention.

FIG. 7-2 is a top view of relevant parts for explaining the forming method of the inverted pyramid texture structure according to the second embodiment of the present invention.

FIG. 7-3 is a top view of relevant parts for explaining the forming method of the inverted pyramid texture structure according to the second embodiment of the present invention.

FIG. 7-4 is a top view of relevant parts for explaining the forming method of the inverted pyramid texture structure according to the second embodiment of the present invention.

FIG. 7-5 is a top view of relevant parts for explaining the forming method of the inverted pyramid texture structure according to the second embodiment of the present invention.

FIG. 7-6 is a top view of relevant parts for explaining the forming method of the inverted pyramid texture structure according to the second embodiment of the present invention.

FIG. 8-1 is a sectional view of relevant parts for explaining the forming method of the inverted pyramid texture structure according to the second embodiment of the present invention.

FIG. 8-2 is a sectional view of relevant parts for explaining the forming method of the inverted pyramid texture structure according to the second embodiment of the present invention.

FIG. 8-3 is a sectional view of relevant parts for explaining the forming method of the inverted pyramid texture structure according to the second embodiment of the present invention.

FIG. 8-4 is a sectional view of relevant parts for explaining the forming method of the inverted pyramid texture structure according to the second embodiment of the present invention.

FIG. 8-5 is a sectional view of relevant parts for explaining the forming method of the inverted pyramid texture structure according to the second embodiment of the present invention.

FIG. 8-6 is a sectional view of relevant parts for explaining the forming method of the inverted pyramid texture structure according to the second embodiment of the present invention.

FIG. 9 is a sectional view of relevant parts for explaining an arrangement of an etching mask according to the second embodiment of the present invention.

### DESCRIPTION OF EMBODIMENTS

Exemplary embodiments of a manufacturing method of a solar cell according to the present invention will be explained below in detail with reference to the drawings. The present invention is not limited to the following descriptions and can be modified as appropriate without departing from the scope of the invention. In the drawings explained below, for easier understanding, the scale of each member may be different from those of actual products. The same applies to relations between the drawings. In addition, even in plan views, hatching may be applied to facilitate visualization of the drawings.

### First Embodiment

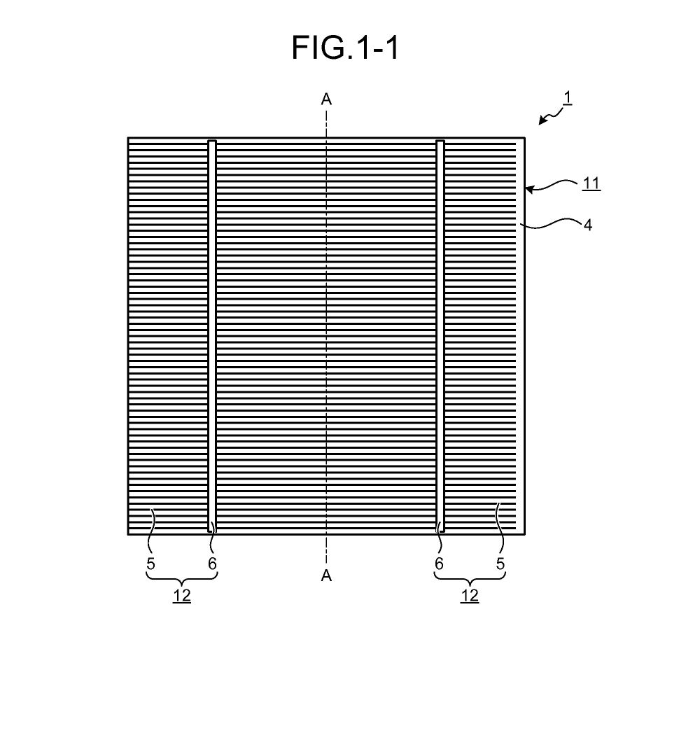

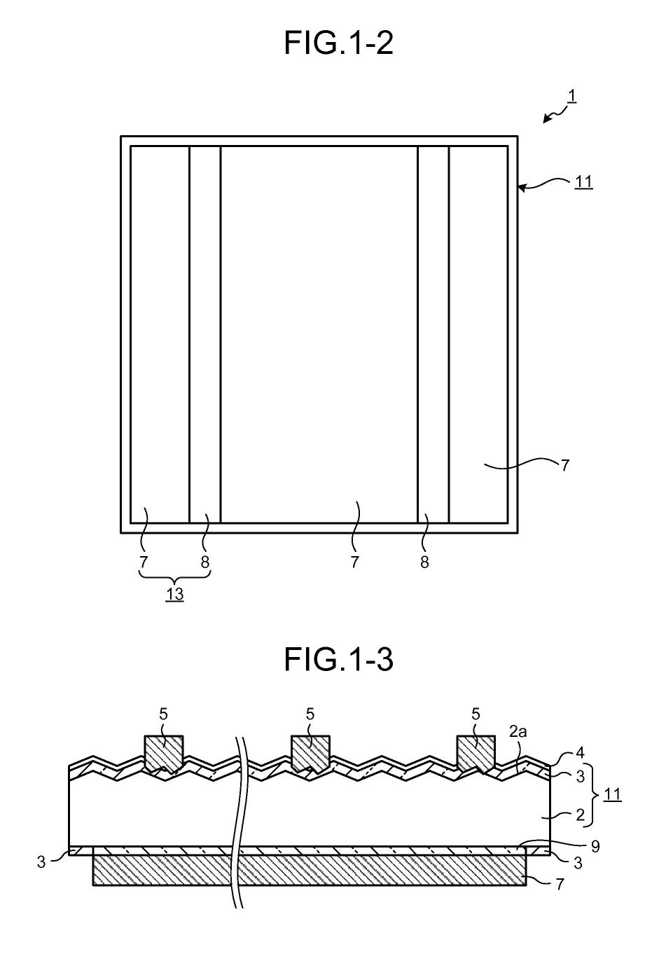

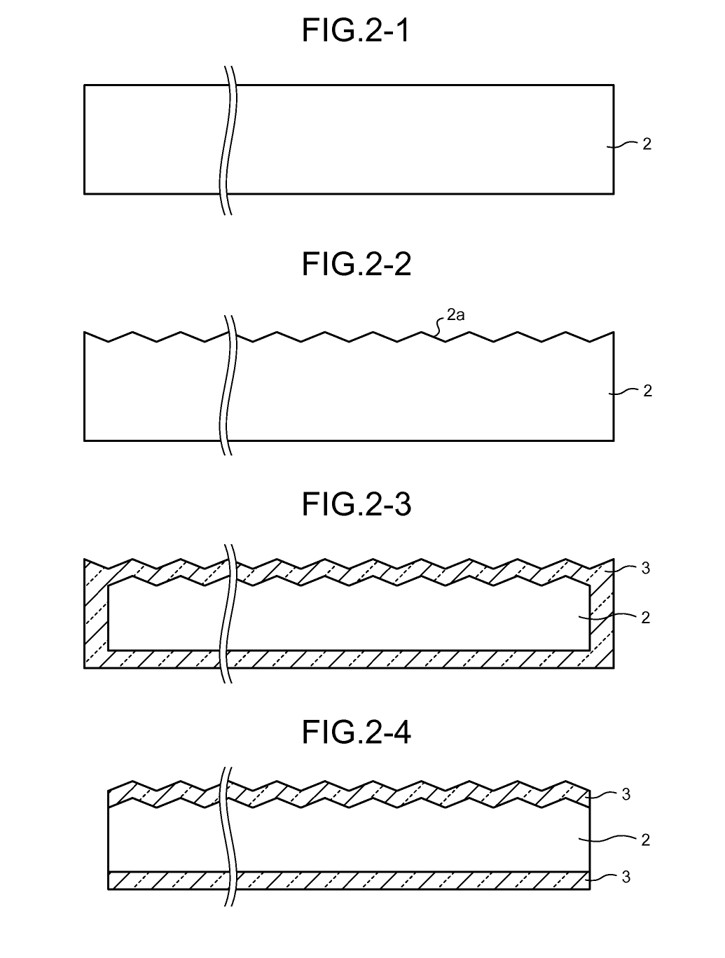

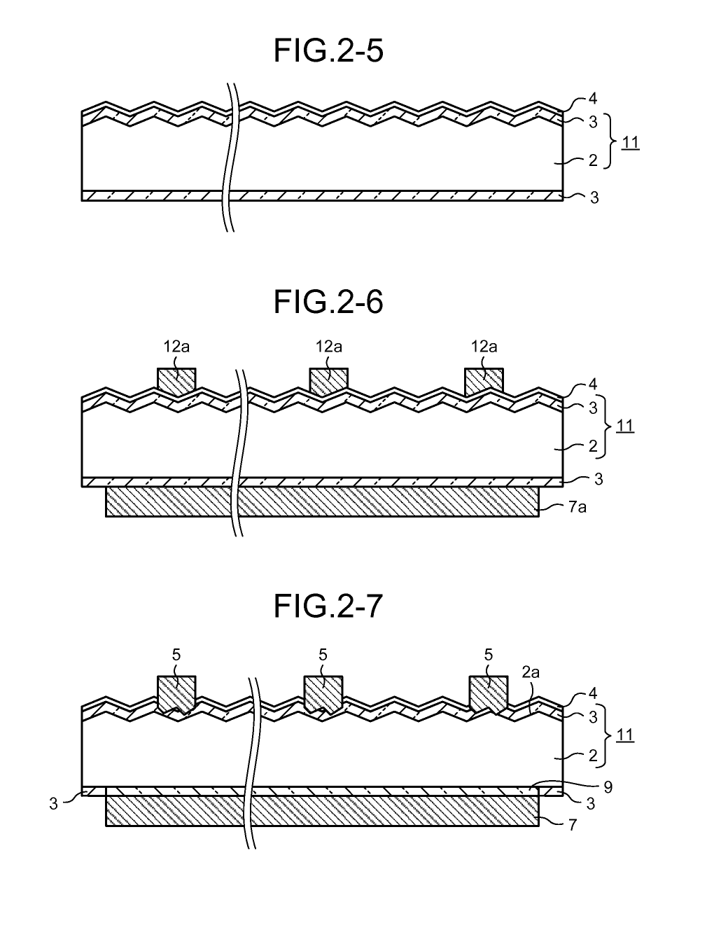

FIGS. 1-1 to 1-3 are explanatory diagrams of the configuration of a solar cell 1 according to a first embodiment of the present invention, where FIG. 1-1 is a top view of the solar cell 1 as viewed from a light receiving surface side, FIG. 1-2 is a bottom view of the solar cell 1 as viewed from the opposite side to the light receiving surface, and FIG. 1-3 is a sectional view of relevant parts of the solar cell 1 along A-A direction in FIG. 1-1.

In the solar cell 1 according to the first embodiment, an n-type impurity diffusion layer 3 is formed on the light receiving surface side of a semiconductor substrate 2 formed of a p-type monocrystalline silicon by phosphorus diffusion, thereby forming a semiconductor substrate 11 having a pn junction. An anti-reflective film 4 formed of a silicon nitride film (SiN film) is formed on the n-type impurity diffusion layer 3. The semiconductor substrate 2 is not limited to the p-type monocrystalline silicon substrate, and a p-type polycrystalline silicon substrate, an n-type polycrystalline silicon substrate, or an n-type monocrystalline silicon substrate can also be used.

An inverted pyramid texture structure including a microasperity (texture) 2a in the inverted pyramid shape is formed on the surface on the light receiving surface side of the semiconductor substrate 11 (the n-type impurity diffusion layer 3) as a texture structure. The microasperity (texture) 2a in the inverted pyramid shape increases the area in the light receiving surface that absorbs light from the outside, and suppresses the reflectance on the light receiving surface to confine the light in the solar cell 1 efficiently.

The anti-reflective film 4 is formed of a silicon nitride film (SiN film), which is an insulating film. The anti-reflective film 4 is not limited to the silicon nitride film (SiN film) and can be formed of an insulating film such as a silicon oxide film (SiO₂ film) or a titanium oxide film (TiO₂ film).

A plurality of long and thin front silver grid electrodes 5 are arranged side by side on the light receiving surface side of the semiconductor substrate 11. Front silver bus electrodes 6 electrically conducted with the front silver grid electrodes 5 are provided substantially orthogonal to the front silver grid electrodes 5, and are electrically connected to the n-type impurity diffusion layer 3 on the bottom surface portion. The front silver grid electrodes 5 and the front silver bus electrodes 6 are made of a silver material.

The front silver grid electrodes 5 have a width of, for example approximately 100 micrometers to 200 micrometers, are arranged substantially parallel to each other at intervals of approximately 2 millimeters, and collect electricity generated in the semiconductor substrate 11. The front silver bus electrodes 6 have a width of, for example, approximately 1 millimeter to 3 millimeters and two to three front silver bus electrodes 6 are arranged per one solar cell. The front silver bus electrodes 6 extract electricity collected by the front silver grid electrodes 5 to the outside. A light-receiving surface side electrode 12, which is a first electrode having a comb-like shape, is formed by the front silver grid electrodes 5 and the front silver bus electrodes 6. Because the light-receiving surface side electrode 12 blocks sunlight incident on the semiconductor substrate 11, it is desired to reduce the area of the light-receiving surface side electrode 12 as much as possible in view of improvement of power generation efficiency. Therefore, the light-receiving surface side electrode 12 is generally arranged as the comb-like front silver grid electrodes 5 and the bar-like front silver bus electrodes 6 as shown in FIG. 1-1.

Silver paste is normally used as a material of the light-receiving surface side electrode of the silicon solar cell, and for example, lead boron glass is added thereto. The glass is in the form of frit, and has a composition of, for example, 5 to 30 wt % of lead (Pb), 5 to 10 wt % of boron (B), 5 to 15 wt % of silicon (Si), and 30 to 60 wt % of oxygen (0). Several wt % of zinc (Zn), cadmium (Cd), and the like is also mixed in some cases. The lead boron glass is dissolved by heating at several hundreds of degrees centigrade (for example, 800° C.), and has a property of eroding silicon at that time. Furthermore, generally, in a manufacturing method of a crystalline silicon solar cell, a method of acquiring an electrical contact between the silicon substrate and the silver paste by using a characteristic of the glass frit is used.

Meanwhile, a back aluminum electrode 7 made of an aluminum material is provided all over the back surface of the semiconductor substrate 11 (the surface opposite to the light receiving surface) excluding a part of the outer peripheral region, and back silver electrodes 8 made of a silver material are provided such that they extend substantially in the same direction as the front silver bus electrodes 6. A back surface-side electrode 13, which is a second electrode, is formed by the back aluminum electrode 7 and the back silver electrodes 8. The BSR (Back Surface Reflection) effect of reflecting long-wavelength light passing through the semiconductor substrate 11 and reusing the light for power generation is expected of the back aluminum electrode 7.

Furthermore, a p+ layer (BSF (Back Surface Field)) 9 containing high-concentration impurities is formed on the surface layer on the back surface side (the surface opposite to the light receiving surface) of the semiconductor substrate 11. The p+ layer (BSF) 9 is provided to acquire the BSF effect, and increases the electron concentration of a p-type layer (the semiconductor substrate 2) with an electric field in a band structure so that electrons in the p-type layer (the semiconductor substrate 2) do not disappear.

In the solar cell 1 having such a configuration, when the semiconductor substrate 11 is irradiated with sunlight from the light receiving surface side of the solar cell 1, holes and electrons are generated. The generated electrons move toward the n-type impurity diffusion layer 3 and the generated holes move toward the semiconductor substrate 2 by the electric field at the pn junction part (the junction plane between the semiconductor substrate 2 formed of the p-type monocrystalline silicon and the n-type impurity diffusion layer 3). Therefore, there are excess electrons in the n-type impurity diffusion layer 3 and there are excess holes in the semiconductor substrate 2. As a result, photovoltaic power is generated. The photovoltaic power is generated in a direction in which the pn junction is forward biased; therefore, the light-receiving surface side electrode 12 connected to the n-type impurity diffusion layer 3 becomes a negative electrode and the back aluminum electrode 7 connected to the p+ layer 9 becomes a positive electrode. Accordingly, electric current flows in an external circuit (not shown).

Next, a manufacturing method of the solar cell 1 according to the first embodiment is explained next with reference to FIGS. 2-1 to 2-7. FIGS. 2-1 to 2-7 are sectional views of relevant parts for explaining an example of the manufacturing process of the solar cell 1 according to the first embodiment.

First, a p-type monocrystalline silicon substrate having a thickness of, for example several hundreds of micrometers, is prepared as the semiconductor substrate 2 (FIG. 2-1). Because the p-type monocrystalline silicon substrate is manufactured by slicing, with a wire saw, an ingot formed by cooling and solidifying molten silicon, damage caused by slicing remains on the surface. Therefore, the p-type monocrystalline silicon substrate is immersed in acid or a heated alkaline solution, for example, in aqueous sodium hydroxide solution to perform etching of the surface thereof, thereby removing the damaged area generated at the time of slicing the silicon substrate and present near the surface of the p-type monocrystalline silicon substrate. For example, the surface is removed by several wt % to 20 wt % caustic soda or carbonated caustic soda and in a thickness of 10 micrometers to 20 micrometers.

Subsequent to the removal of the damaged area, anisotropic etching is performed on the p-type monocrystalline silicon substrate with a solution in which IPA (isopropyl alcohol) is added to a similar low concentration alkaline solution, and the inverted pyramid texture structure formed of the microasperity (texture) 2a in the inverted pyramid shape is formed on the surface on the light receiving surface side of the p-type monocrystalline silicon substrate so as to expose the silicon (111) surface (FIG. 2-2). Such an inverted pyramid texture structure is provided on the light receiving surface side of the p-type monocrystalline silicon substrate to cause multiple reflection of light on the front surface side of the solar cell 1, and light incident on the solar cell 1 can be efficiently absorbed into the semiconductor substrate 11; therefore, the reflectance is effectively reduced and thus the photoelectric conversion efficiency can be improved. When removal of the damaged layer and formation of the texture structure are performed by using the alkaline solution, continuous processing is performed in some cases by adjusting the concentration of the alkaline solution according to individual purposes. A forming method of the inverted pyramid texture structure is described later.

A case where the inverted pyramid texture structure is formed on the surface on the light receiving surface side of the p-type monocrystalline silicon substrate is shown here. However, the inverted pyramid texture structure can be formed on both surfaces of the p-type monocrystalline silicon substrate. When the inverted pyramid texture structure is formed also on the back surface of the p-type monocrystalline silicon substrate, light reflected by the back surface-side electrode 13 and returned to the semiconductor substrate 11 can be scattered.

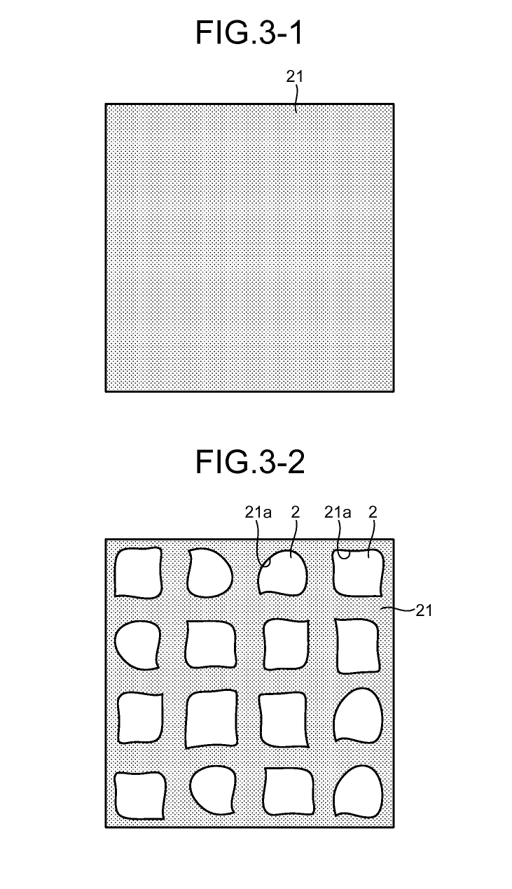

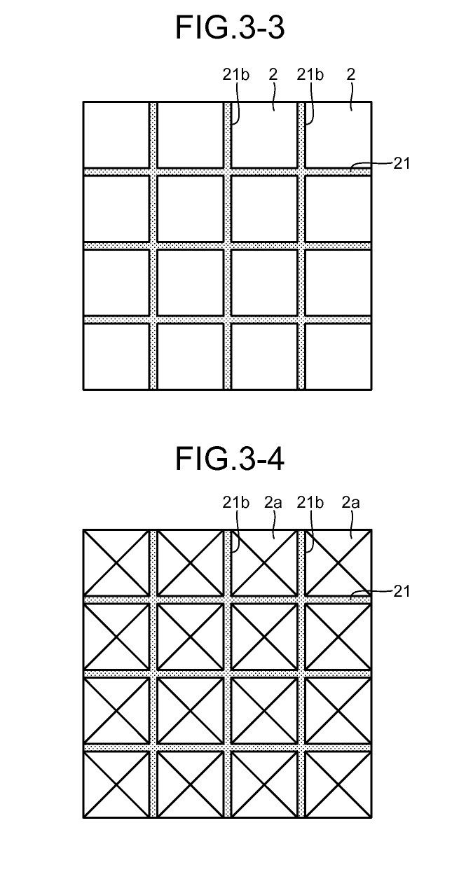

Subsequently, the pn junction is formed on the semiconductor substrate 2 (FIG. 2-3). Specifically, for example, a V group element, such as phosphorus (P), is diffused in the semiconductor substrate 2 to form the n-type impurity diffusion layer 3 having a thickness of several hundreds of nanometers. In this case, the pn junction is formed by diffusing phosphorus oxychloride (POCl₃), by thermal diffusion, into the p-type monocrystalline silicon substrate on which the inverted pyramid texture structure is formed on the light receiving surface side. Consequently, the n-type impurity diffusion layer 3 is formed on the entire surface of the p-type monocrystalline silicon substrate.

In this diffusion process, thermal diffusion is performed on the p-type monocrystalline silicon substrate in a mixed gas atmosphere of, for example, phosphorus oxychloride (POCl₃) gas, nitrogen gas, and oxygen gas by a gas-phase diffusion method at a high temperature of, for example 800° C. to 900° C., for several tens of minutes, thereby uniformly forming the n-type impurity diffusion layer 3 in which phosphorus (P) is diffused in the surface layer of the p-type monocrystalline silicon substrate. When the sheet resistance of the n-type impurity diffusion layer 3 formed on the surface of the semiconductor substrate 2 is in a range of 30 Ω/□ to 80 Ω/□, excellent electric characteristic of the solar cell can be acquired.

Subsequently, pn separation is performed for electrically insulating the back surface-side electrode 13, which is a p-type electrode, and the light-receiving surface side electrode 12, which is an n-type electrode, from each other (FIG. 2-4). Because the n-type impurity diffusion layer 3 is uniformly formed on the surface of the p-type monocrystalline silicon substrate, the front surface and back surface are electrically connected to each other. Therefore, when the back surface-side electrode 13 (the p-type electrode) and the light-receiving surface side electrode 12 (the n-type electrode) are formed, the back surface-side electrode 13 (the p-type electrode) and the light-receiving surface side electrode 12 (the n-type electrode) are electrically connected. To interrupt the electrical connection, pn separation is performed by removing the n-type impurity diffusion layer 3 formed in the facet region of the p-type monocrystalline silicon substrate by dry etching. As another method performed to remove the influence of the n-type impurity diffusion layer 3, there is a method of performing facet separation by a laser.

Because a glassy (PSG: Phospho-Silicate Glass) layer deposited on the surface during a diffusion process is formed on the surface of the p-type monocrystalline silicon substrate immediately after formation of the n-type impurity diffusion layer 3, the phosphorus glass layer is removed by using a hydrofluoric acid solution or the like. With this process, the semiconductor substrate 11 is acquired, in which a pn junction is formed by the semiconductor substrate 2 formed of the p-type monocrystalline silicon substrate, which is a first conductivity type layer, and the n-type impurity diffusion layer 3, which is a second conductivity type layer formed on the light receiving surface side of the semiconductor substrate 2.

The anti-reflective film 4 is then formed in a uniform thickness on the light receiving surface side (the n-type impurity diffusion layer 3) of the p-type monocrystalline silicon substrate to improve the photoelectric conversion efficiency (FIG. 2-5). The film thickness and the refractive index of the anti-reflective film 4 are set to values with which light reflection can be suppressed most effectively. When the anti-reflective film 4 is formed, a silicon nitride film is formed as the anti-reflective film 4, for example, by a plasma CVD method using a mixed gas of silane (SiH₄) gas and ammonia (NH₃) gas as a raw material, at a temperature of 300° C. or higher under reduced pressure. The refractive index is, for example, approximately 2.0 to 2.2, and the most appropriate thickness of the anti-reflective film is, for example, approximately 70 nanometers to 90 nanometers. A film having two or more layers having different refractive indexes can be laminated as the anti-reflective film 4. A deposition method, a thermal CVD method, or the like can be used other than the plasma CVD method as the forming method of the anti-reflective film 4. It is to be noted that the anti-reflective film 4 formed in this manner is an insulating body and the structure obtained by simply forming the light-receiving surface side electrode 12 on the anti-reflective film 4 does not function as a solar cell.

Electrodes are then formed by screen printing. The light-receiving surface side electrode 12 is manufactured first (before baking). Specifically, a silver paste 12a, which is an electrode material paste including a glass frit, is applied onto the anti-reflective film 4, which is the light receiving surface of the p-type monocrystalline silicon substrate, in the shape of the front silver grid electrodes 5 and the front silver bus electrodes 6 by screen printing and the silver paste 12a is dried (FIG. 2-6).

Next, an aluminum paste 7a, which is an electrode material paste, is applied in the shape of the back aluminum electrode 7 and a silver paste 8a, which is an electrode material paste, is further applied in the shape of the back silver electrodes 8 to the back surface side of the p-type monocrystalline silicon substrate by screen printing, and the aluminum paste 7a and the silver paste 8a are dried (FIG. 2-6). In FIG. 2-6, only the aluminum paste 7a is shown and the silver paste 8a is not shown.

Subsequently, by simultaneously baking the electrode pastes on the light receiving surface side and the back surface side of the semiconductor substrate 11, for example, at a temperature of 600° C. to 900° C., on the front surface side of the semiconductor substrate 11, the silver material comes in contact with silicon and is re-solidified while the anti-reflective film 4 is melting by the glass material contained in the silver paste 12a. Accordingly, the front silver grid electrodes 5 and the front silver bus electrodes 6 as the light-receiving surface side electrode 12 are acquired, and conduction between the light-receiving surface side electrode 12 and silicon of the semiconductor substrate 11 is ensured (FIG. 2-7). This process is referred to as “fire-through method”.

The aluminum paste 7a also reacts with silicon of the semiconductor substrate 11 and the back aluminum electrode 7 is acquired, and the p+ layer 9 is formed immediately below the back aluminum electrode 7. The silver material of the silver paste 8a comes in contact with silicon and is re-solidified, thereby acquiring the back silver electrodes 8 (FIG. 2-7). In FIG. 2-7, only the front silver grid electrodes 5 and the back aluminum electrode 7 are shown, and the front silver bus electrodes 6 and the silver paste 8a are not shown.

The solar cell 1 according to the present embodiment shown in FIGS. 1-1 to 1-3 can be manufactured by performing the processes described above. The order in which the paste that is an electrode material is applied to the light receiving surface side and the back surface side of the semiconductor substrate 11 can be changed.

A forming method of the inverted pyramid texture structure is explained next with reference to FIGS. 3-1 to 3-4 and FIGS. 4-1 to 4-4. FIGS. 3-1 to 3-4 are top views of relevant parts for explaining the forming method of the inverted pyramid texture structure according to the first embodiment. FIGS. 4-1 to 4-4 are sectional views of relevant parts for explaining the forming method of the inverted pyramid texture structure according to the first embodiment. Although FIGS. 3-1 to 3-4 are plan views, hatching is added to FIGS. 3-1 to 3-4 to facilitate visualization of the drawings.

First, a silicon nitride film (SiN film) 21 is formed as a protection film to be used as an etching mask on the light receiving surface side of the p-type monocrystalline silicon substrate having undergone damage removal with a film thickness of approximately 70 nanometers to 90 nanometers by the plasma CVD method (FIGS. 3-1 and 4-1). A different film such as a silicon oxide film (SiO₂ film) can be formed instead of the silicon nitride film (SiN film) 21. The silicon oxide film (SiO₂ film) can be formed by, for example, the plasma CVD method or thermal oxidation.

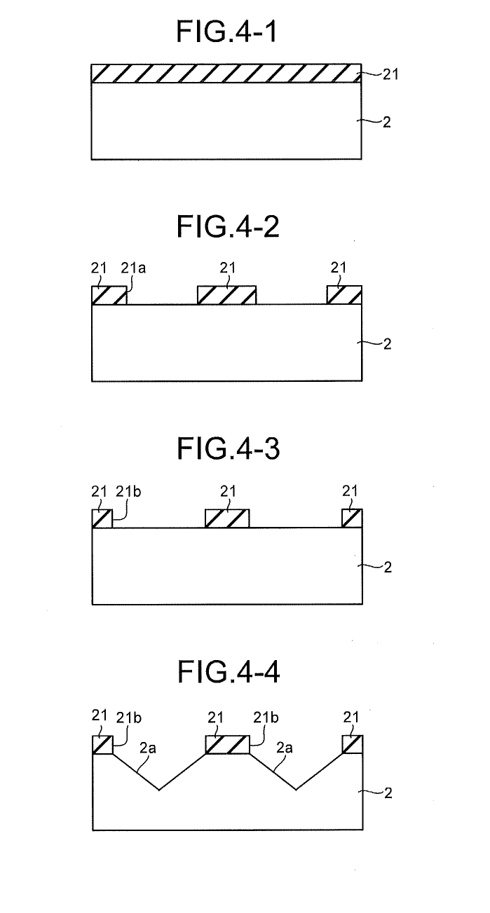

Next, openings having a desired size are formed in the silicon nitride film (SiN film) 21 according to the size of the microasperity 2a in the inverted pyramid shape to be formed. The openings are formed by processing in two stages. Specifically, in the first processing step, first openings 21a having shapes close to the target opening shape and sizes slightly smaller than the target opening size are formed (FIGS. 3-2 and 4-2). In the second processing step, second openings 21b having the target opening size are formed (FIGS. 3-3 and 4-3). In the first processing step, the first openings 21a are formed in the silicon nitride film (SiN film) 21 by a method having relatively high productivity, that is, having high processing efficiency. Meanwhile, in the second processing step, the second openings 21b are formed in the silicon nitride film (SiN film) 21 by a method having relatively high processing controllability, that is, having high processing accuracy.

In the first processing step, the first openings 21a having a diameter of approximately several tens of micrometers are formed in the silicon nitride film (SiN film) 21 by using etching paste. By using etching paste, it is possible to process an etching mask having high productivity, that is, having high processing efficiency by simple and less number of processes, i.e., printing, heating up to a temperature at which etching proceeds, and cleaning. As another opening method in the first processing step, the first openings 21a having a diameter of approximately several tens of micrometers can be formed also by irradiation with a laser beam having an enlarged laser diameter obtained by converting a laser beam into a divergent beam. Etching paste and irradiation with the laser beam can be concurrently used appropriately according to the opening shape and the like. Because these methods to be used in the first processing step are inferior in controllability, that is, processing accuracy, for example, as shown in FIG. 3-2, the shape is deviated from the target opening shape.

In the second processing step, the laser beam is converged to a diameter of approximately several micrometers to be reduced to a size smaller than the first openings 21a. By irradiating the silicon nitride film (SiN film) 21 with such a small-diameter laser beam, for example, KrF excimer laser of 248 nanometers, or a frequency-doubled (532 nanometers) or frequency-tripled (355 nanometers) YAG laser, microfabrication (trimming) is performed to expand the first openings 21a up to the target opening shape, thereby forming the second openings 21b. By using the laser, processing of a fine etching mask having high controllability, that is, having high processing accuracy can be performed with a simple process.

Next, anisotropic etching is performed on the p-type monocrystalline silicon substrate with an etching solution in which IPA is added to a low-concentration alkaline solution, such as several wt % sodium hydroxide or potassium hydroxide, to form the inverted pyramid texture structure formed of the microasperity (texture) 2a in the inverted pyramid shape on the surface on the light receiving surface side of the p-type monocrystalline silicon substrate so as to expose the silicon (111) surface (FIGS. 3-4 and 4-4). The anisotropic etching of the p-type monocrystalline silicon substrate is performed by using the silicon nitride film (SiN film) 21, in which the second openings 21b are formed, as the etching mask under such a condition that the etching mask has a resistance. On the surface of the p-type monocrystalline silicon substrate, etching proceeds due to the etching solution entering from the second openings 21b, and the slow-reacting (111) surface is exposed, thereby forming the inverted pyramid texture structure formed of the microasperity (texture) 2a in the inverted pyramid shape.

Finally, the p-type monocrystalline silicon substrate is immersed in a hydrofluoric acid solution or the like to remove the silicon nitride film (SiN film) 21, which is the remaining etching mask. With this process, as shown in FIG. 2-2, the inverted pyramid texture structure formed of the microasperity (texture) 2a in the inverted pyramid shape is acquired on the surface of the p-type monocrystalline silicon substrate.

With reference to FIGS. 5-1 to 5-3 and FIGS. 6-1 to 6-3, a forming method of an inverted pyramid texture structure in a conventional manufacturing method of a solar cell is explained for comparison. FIGS. 5-1 to 5-3 are top views of relevant parts for explaining a forming method of an inverted pyramid texture structure in a conventional manufacturing method of a solar cell. FIGS. 6-1 to 6-3 are sectional views of relevant parts for explaining the forming method of the inverted pyramid texture structure in the conventional manufacturing method of a solar cell. Although FIGS. 5-1 to 5-3 are plan views, hatching is added to FIGS. 5-1 to 5-3 to facilitate visualization of the drawings.

First, a silicon nitride film (SiN film) 121, which becomes an etching mask, is formed on the light receiving surface side of a semiconductor substrate 102 (a p-type monocrystalline silicon substrate) having undergone damage removal with a film thickness of approximately 70 nanometers to 90 nanometers by the plasma CVD method (FIGS. 5-1 and 6-1).

Next, openings 121a having a desired size are formed in the silicon nitride film (SiN film) 121 according to the size of a microasperity 102a in the inverted pyramid shape to be formed (FIGS. 5-2 and 6-2). The openings are formed by photolithography, which is a general method. Specifically, application of a photoresist to the silicon nitride film (SiN film) 121, baking processing, exposure by using a photomask, development, and baking are sequentially performed. With this process, the openings 121a are formed in the silicon nitride film (SiN film) 121.

Next, etching of the silicon nitride film (SiN film) 121 via the openings 121a using an alkaline aqueous solution and photoresist removal are sequentially performed (FIGS. 5-3 and 6-3). Anisotropic etching of the semiconductor substrate 102 is performed by using the silicon nitride film (SiN film) 121, in which the openings 121 are formed, as the etching mask under such a condition that the etching mask has a resistance. The inverted pyramid texture structure is formed by performing the processes described above. In this manner, in the conventional method, because many processes need to be performed, the processes become complicated and a processing time becomes long; therefore, there is a problem in productivity.

As described above, in the manufacturing method of a solar cell according to the first embodiment, the process of forming the openings in the etching mask at the time of forming the inverted pyramid texture structure is performed by dividing the process into two stages, i.e., the first processing step of forming the first openings 21a having shapes close to the target opening shape and sizes slightly smaller than the target opening size by a method having relatively high productivity, that is, having high processing efficiency and the second processing step of forming the second openings 21b by expanding the first openings 21a up to the target opening shape by a method having relatively high processing controllability, that is, having high processing accuracy. With this process, the openings can be formed in the etching mask accurately in a short time and with simple and less number of processes.

Therefore, according to the manufacturing method of a solar cell of the first embodiment, the inverted pyramid texture structure can be formed with good productivity and with high accuracy, and the solar cell having excellent photoelectric conversion efficiency can be manufactured with good productivity.

### Second Embodiment

In a second embodiment, an explanation will be made of a method of forming the inverted pyramid texture structure and forming a selective emitter by changing the impurity concentration of the n-type impurity diffusion layer in a region under the light-receiving surface side electrode 12 to a high concentration. By this method, the contact resistance between the light-receiving surface side electrode 12 and the n-type impurity diffusion layer 3 can be reduced, and the photoelectric conversion efficiency of the solar cell can be improved. Because the basic configuration of a solar cell formed according to the second embodiment is the same as that of the solar cell 1 in the first embodiment except for the structure of the n-type impurity diffusion layer 3, reference is made to the explanations and the drawings in the first embodiment.

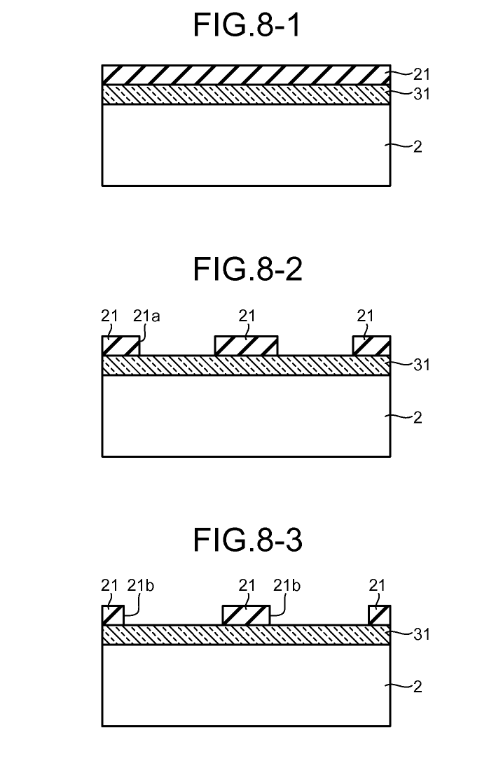

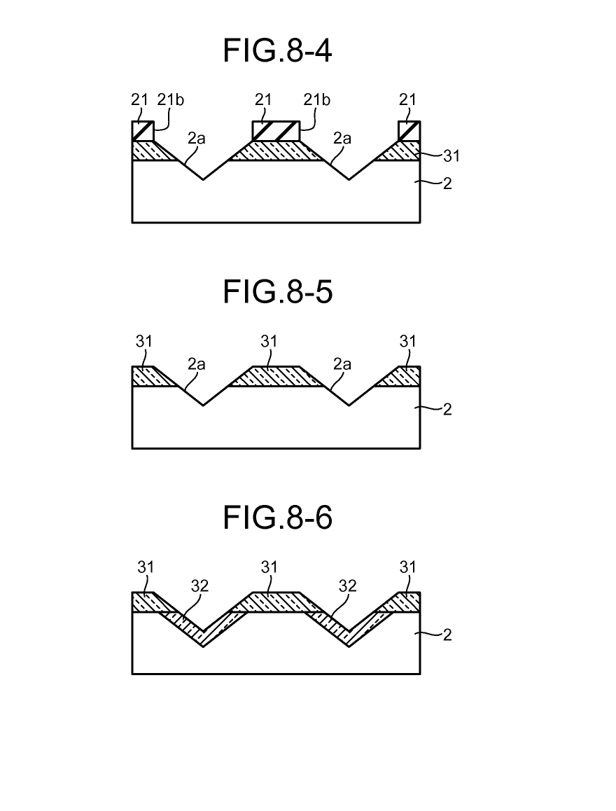

A manufacturing method of a solar cell according to the second embodiment is explained with reference to FIGS. 7-1 to 7-6 and 8-1 to 8-6. FIGS. 7-1 to 7-6 are top views of relevant parts for explaining the forming method of the inverted pyramid texture structure according to the second embodiment. FIGS. 8-1 to 8-6 are sectional views of relevant parts for explaining the forming method of the inverted pyramid texture structure according to the second embodiment. While FIGS. 7-1 to 7-6 are plan views, hatching is added thereto to facilitate visualization of the drawings.

First, similarly to the case of the first embodiment, the p-type monocrystalline silicon substrate having a thickness of, for example, several hundreds of micrometers, is prepared as the semiconductor substrate 2 and a damaged area is removed. Subsequently, a high-concentration (low-resistance) n-type impurity diffusion layer 31 having a thickness of several hundreds of nanometers is formed on the surface of the light receiving surface side of the p-type monocrystalline silicon substrate by the method similar to that in the first embodiment. In the impurity diffusion at this time, phosphorus (P) is diffused in a high concentration (first concentration) so that the sheet resistance of the n-type impurity diffusion layer 31 becomes approximately 30 Ω/□ to 50 Ω/□.

Because a glassy (PSG: Phospho-Silicate Glass) layer deposited on the surface during a diffusion process is formed on the surface of the p-type monocrystalline silicon substrate immediately after formation of the n-type impurity diffusion layer 31, the phosphorus glass layer is removed by using a hydrofluoric acid solution or the like. Because the impurity diffusion is performed again in the subsequent processes, pn separation is not performed here.

The silicon nitride film (SiN film) 21, which becomes an etching mask, is then formed on the n-type impurity diffusion layer 31 with a film thickness of approximately 70 nanometers to 90 nanometers by the plasma CVD method (FIGS. 7-1 and 8-1). A different film such as a silicon oxide film (SiO₂ film) can be formed instead of the silicon nitride film (SiN film) 21.

Next, openings having a desired size are formed in the silicon nitride film (SiN film) 21 according to the size of the microasperity 2a in the inverted pyramid shape to be formed. The openings are formed by performing processing in two stages. Specifically, in the first processing step, the first openings 21a having shapes close to the target opening shape and sizes slightly smaller than the target opening size are formed (FIGS. 7-2 and 8-2). Thereafter, in the second processing step, the second openings 21b having the target opening size are formed (FIGS. 7-3 and 8-3). In the first processing step, the first openings 21a are formed in the silicon nitride film (SiN film) 21 by a method having relatively high productivity, that is, having high processing efficiency. Meanwhile, in the second processing step, the second openings 21b are formed in the silicon nitride film (SiN film) 21 by a method having relatively high controllability, that is, having high processing accuracy.

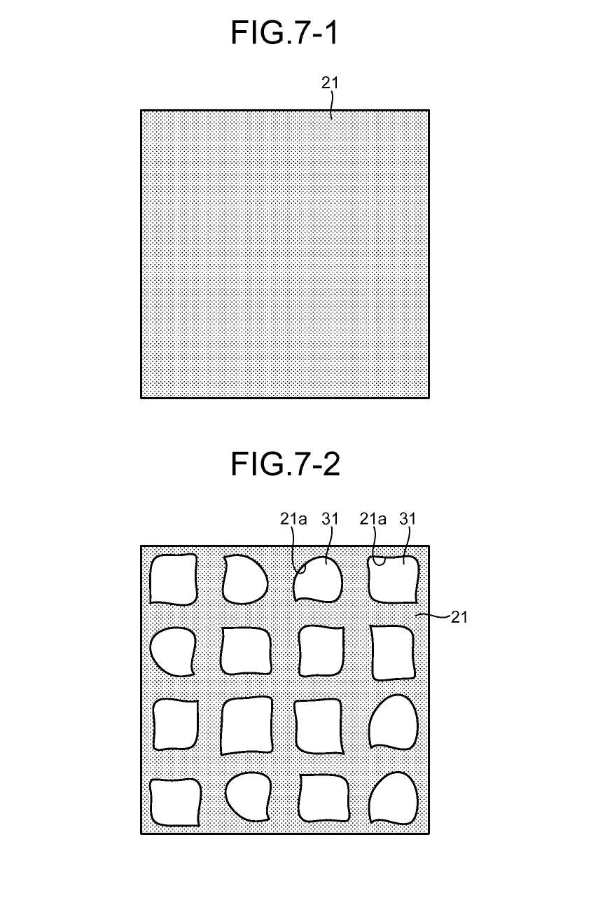

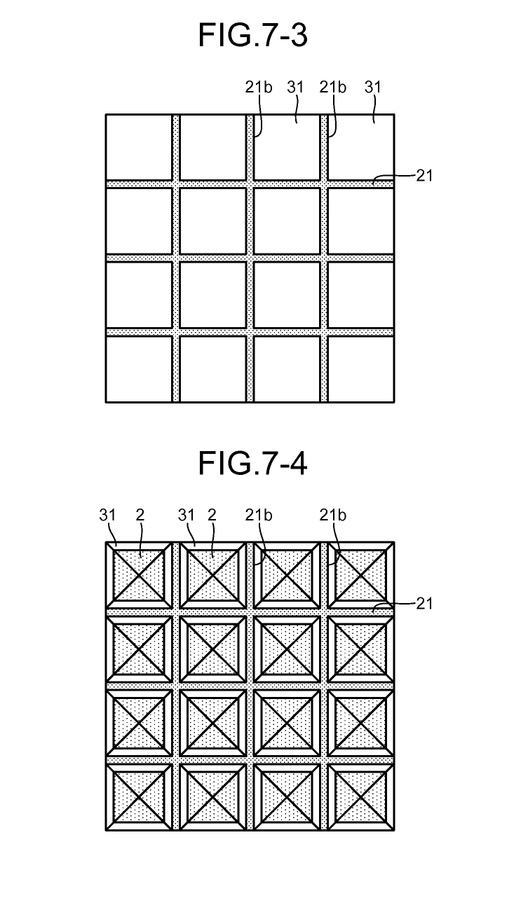

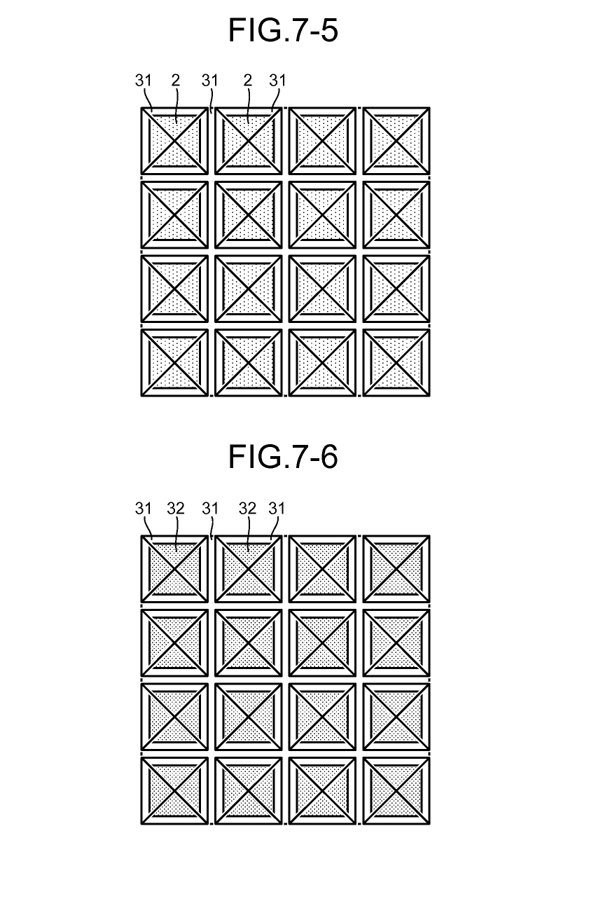

In the first processing step, the first openings 21a having a diameter of approximately several tens of micrometers are formed in the silicon nitride film (SiN film) 21 by using etching paste. By using the etching paste, it is possible to process an etching mask having high productivity, that is, having high processing efficiency by simple processes, i.e., printing, heating up to a temperature at which etching proceeds, and cleaning. Because these methods to be used in the first processing step are inferior in controllability, that is, processing accuracy, for example, as shown in FIG. 7-2, the shape is deviated from the target opening shape.

In the second processing step, by irradiating the silicon nitride film (SiN film) 21 with a laser beam with a diameter being focused to approximately several micrometers, such as KrF excimer laser of 248 nanometers, or a frequency-doubled (532 nanometers) or frequency-tripled (355 nanometers) YAG laser, microfabrication (trimming) is performed to expand the first openings 21a up to the target opening shape, thereby forming the second openings 21b. By using the laser beam, processing of a fine etching mask having high controllability, that is, having high processing accuracy can be performed with a simple process.

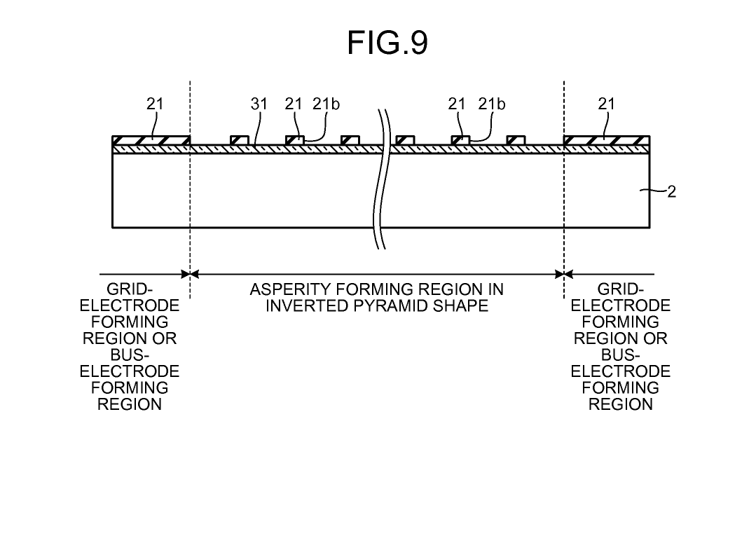

In the second embodiment, in the region where the light-receiving surface side electrode 12, which includes the front silver grid electrodes 5 and the front silver bus electrodes 6, is formed in the subsequent processes, as shown in FIG. 9, the etching mask remains without forming the second openings 21b in the etching mask. With this process, the high-concentration (low-resistance) n-type impurity diffusion layer 31 remains in the region where the light-receiving surface side electrode 12 is formed after the inverted pyramid texture structure is formed, thereby enabling the contact resistance between the light-receiving surface side electrode 12 and the silicon substrate to be reduced and the photoelectric conversion efficiency to be improved. FIG. 9 is a sectional view of relevant parts for explaining the arrangement of the etching mask according to the second embodiment.

Next, anisotropic etching is performed on the p-type monocrystalline silicon substrate with an etching solution in which IPA is added to a low-concentration alkaline solution, such as several wt % sodium hydroxide or potassium hydroxide, to form the inverted pyramid texture structure formed of the microasperity (texture) 2a in the inverted pyramid shape on the surface on the light receiving surface side of the p-type monocrystalline silicon substrate so as to expose the silicon (111) surface (FIGS. 7-4 and 8-4). The anisotropic etching of the p-type monocrystalline silicon substrate is performed by using the silicon nitride film (SiN film) 21, in which the second openings 21b are formed, as the etching mask under such a condition that the etching mask has a resistance. On the surface of the p-type monocrystalline silicon substrate, etching of the high-concentration (low-resistance) n-type impurity diffusion layer 31 and the p-type monocrystalline silicon substrate proceeds due to the etching solution entering from the second openings 21b, and the slow-reacting (111) surface is exposed, thereby forming the inverted pyramid texture structure formed of the microasperity (texture) 2a in the inverted pyramid shape. In other words, the high-concentration (low-resistance) n-type impurity diffusion layer 31 and the p-type monocrystalline silicon substrate are exposed on the surfaces of the concave portions of the microasperity (texture) 2a in the inverted pyramid shape.

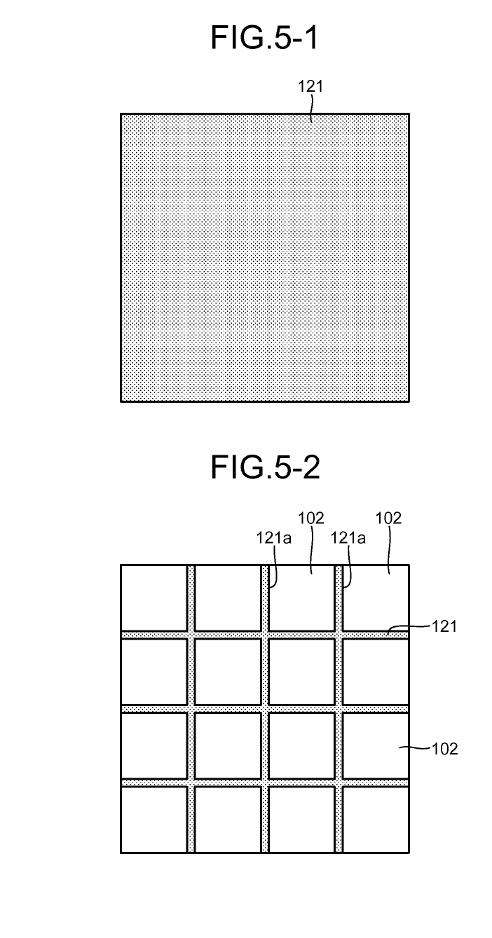

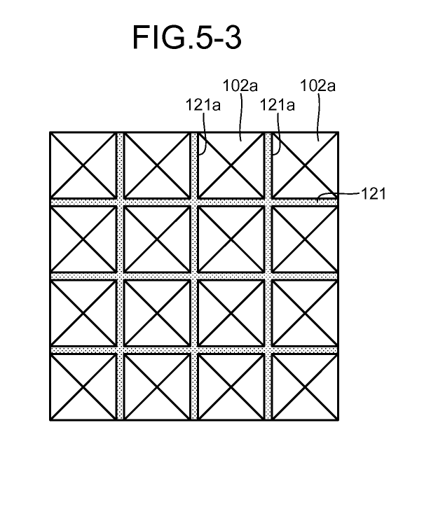

The silicon nitride film (SiN film) 21, which is the remaining etching mask, is then immersed in a hydrofluoric acid solution or the like and removed (FIGS. 7-5 and 8-5). With this process, the texture structure formed of the microasperity (texture) 2a in the inverted pyramid shape is acquired on the surface of the p-type monocrystalline silicon substrate.

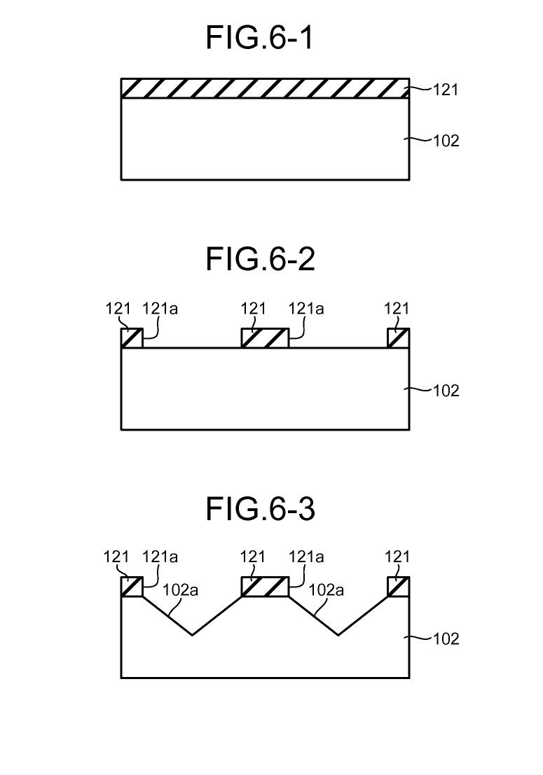

A low-concentration (high-resistance) n-type impurity diffusion layer 32 having a thickness of several hundreds of nanometers is then formed on the exposed surface of the p-type monocrystalline silicon substrate in the microasperity (texture) 2a in the inverted pyramid shape by performing the impurity diffusion process again (FIGS. 7-6 and 8-6). In impurity diffusion at this time, phosphorus (P) is diffused in a low concentration (second concentration), which is lower than the first concentration, so that the sheet resistance of the n-type impurity diffusion layer 32 becomes approximately 60 Ω/□ to 100 Ω/□. With this process, the low-concentration (high-resistance) n-type impurity diffusion layer 32 is formed on the exposed surface of the p-type monocrystalline silicon substrate in the microasperity (texture) 2a in the inverted pyramid shape.

Next, similarly to the case of the first embodiment, pn separation is performed for electrically insulating the back surface-side electrode 13, which is a p-type electrode, and the light-receiving surface side electrode 12, which is an n-type electrode, from each other. The phosphorus glass layer formed on the surface of the p-type monocrystalline silicon substrate at the time of forming the low-concentration (high-resistance) n-type impurity diffusion layer 32 is removed by using a hydrofluoric acid solution or the like. With this process, the semiconductor substrate 11 is acquired, in which a pn junction is formed by the semiconductor substrate 2 formed of the p-type monocrystalline silicon substrate, which is a first conductivity type layer, and the n-type impurity diffusion layer 3, which is a second conductivity type layer formed on the light receiving surface side of the semiconductor substrate 2 and includes the high-concentration (low-resistance) n-type impurity diffusion layer 31 and the low-concentration (high-resistance) n-type impurity diffusion layer 32 (not shown).

Thereafter, similarly to the case of the first embodiment, the anti-reflective film 4, the light-receiving surface side electrode 12, and the back surface-side electrode 13 are formed to complete a solar cell having the inverted pyramid texture structure.

As described above, in the manufacturing method of a solar cell according to the second embodiment, the process of forming the openings in the etching mask at the time of forming the inverted pyramid texture structure is performed by dividing the process into two stages, i.e., the first processing step of forming the first openings 21a having shapes close to the target opening shape and sizes slightly smaller than the target opening size by a method having relatively high productivity, that is, having high processing efficiency and the second processing step of forming the second openings 21b by expanding the first openings 21a up to the target opening shape by a method having relatively high processing controllability, that is, having high processing accuracy. With this process, the openings can be formed in the etching mask accurately, in a short time, and with simple and less number of processes.

Therefore, according to the manufacturing method of a solar cell of the second embodiment, the inverted pyramid texture structure can be formed with good productivity and with high accuracy, and the solar cell having excellent photoelectric conversion efficiency can be manufactured with good productivity.

Furthermore, in the manufacturing method of a solar cell according to the second embodiment, the inverted pyramid texture structure is formed and the selective emitter is also formed by changing the impurity concentration of the n-type impurity diffusion layer in the region under the light-receiving surface side electrode 12 to a high concentration. With this process, the contact resistance between the light-receiving surface side electrode 12 and the n-type impurity diffusion layer 3 can be reduced, and the photoelectric conversion efficiency of the solar cell can be improved.

By forming a plurality of solar cells having the configuration explained in the above embodiments, and electrically connecting adjacent solar cells, a solar cell module having an excellent optical confinement effect and excellent photoelectric conversion efficiency can be realized. In this case, it suffices that the light-receiving surface side electrode 12 of one of the adjacent solar cells and the back surface-side electrode 13 of the other one of the solar cells are electrically connected.

### INDUSTRIAL APPLICABILITY

As described above, the manufacturing method of a solar cell according to the present invention is useful for improving the productivity of a solar cell having an inverted pyramid texture structure and excellent photoelectric conversion efficiency.

### REFERENCE SIGNS LIST

1 solar cell
2 semiconductor substrate
2a microasperity (texture) in inverted pyramid shape
3 n-type impurity diffusion layer
4 anti-reflective film
5 front silver grid electrode
6 front silver bus electrode
7 back aluminum electrode
7a aluminum paste
8 back silver electrode
8a silver paste
p+ layer (BSF (Back Surface Field))
11 semiconductor substrate
12 light-receiving surface side electrode
12a silver paste
13 back surface-side electrode
21a first opening
21b second opening
31 high-concentration (low-resistance) n-type impurity diffusion layer
32 low-concentration (high-resistance) n-type impurity diffusion layer

1. A manufacturing method of a solar cell comprising:
a first step of forming an impurity diffusion layer by diffusing an impurity element having a second conductivity type on one surface side of a semiconductor substrate having a first conductivity type;
a second step of forming, on the one surface side of the semiconductor substrate, a light-receiving surface side electrode that is electrically connected to the impurity diffusion layer; and
a third step of forming a back surface-side electrode on another surface side of the semiconductor substrate, wherein
the manufacturing method includes a fourth step of forming an asperity structure having a concave portion in an inverted pyramid shape on a surface of the one surface side of the semiconductor substrate at any point in time before the second step, and
the fourth step includes
a protection-film forming step of forming a protection film on the one surface side of the semiconductor substrate,
a first processing step of forming a plurality of first openings having a shape close to a desired opening shape and a size smaller than a target opening size in the protection film by a method having relatively high processing efficiency,
a second processing step of forming second openings in the protection film by expanding the first openings up to the target opening size by a method having relatively high processing accuracy,
an etching step of forming the asperity structure having the concave portion in the inverted pyramid shape on the one surface side of the semiconductor substrate by performing anisotropic wet etching on the semiconductor substrate in a region under the second openings via the second openings, and
a removing step of removing the protection film.

2. The manufacturing method of a solar cell according to claim 1, wherein the first processing step includes forming the first openings by applying etching paste to the protection film.

3. The manufacturing method of a solar cell according to claim 1, wherein the first processing step includes forming the first openings by irradiating the protection film with a divergent laser beam with an enlarged laser diameter.

4. The manufacturing method of a solar cell according to claim 1, wherein the second processing step includes forming the second openings by irradiating the protection film with a laser beam with a laser diameter smaller than the first openings.

5. The manufacturing method of a solar cell according to claim 1, wherein the first step is performed after performing the fourth step.

6. The manufacturing method of a solar cell according to claim 1, wherein
the protection-film forming step includes, after forming a first impurity diffusion layer by diffusing the impurity element in a first concentration on the one surface side of the semiconductor substrate, forming the protection film on the first impurity diffusion layer,
the etching step includes, by performing anisotropic wet etching on the first impurity diffusion layer in the region under the second openings and the semiconductor substrate under the first impurity diffusion layer via the second openings, forming, on the one surface side of the semiconductor substrate, the asperity structure in which the first impurity diffusion layer and the semiconductor substrate are exposed on an inner surface of the concave portion, and
the manufacturing method includes a step of, after the etching step, forming a second impurity diffusion layer by diffusing the impurity element in a second concentration, which is lower than the first concentration, on a surface of the semiconductor substrate exposed on the inner surface of the concave portion.

7. The manufacturing method of a solar cell according to claim 6, wherein the second processing step includes forming the second openings in a region excluding a forming region, in which the light-receiving surface side electrode is formed, in the protection film.
